(19) United States
(12) Patent Application Publication
(10) Pub. No.: US 2024/0145363 A1
(43) Pub. Date: May 2, 2024

(54) FAN-OUT PACKAGE HAVING BALL GRID ARRAY SUBSTRATE WITH SIGNAL AND POWER METALLIZATION

(71) Applicant: TEXAS INSTRUMENTS INCORPORATED, Dallas, TX (US)

(72) Inventors: Vivek SRIDHARAN, Dallas, TX (US); Yiqi TANG, Allen, TX (US); Blake TRAVIS, Richardson, TX (US); Dibyajat MISHRA, Plano, TX (US); Deepa KOTE, Richardson, TX (US)

(21) Appl. No.: 17/977,091

(22) Filed: Oct. 31, 2022

(51) Int. Cl. H01L 23/498; H01L 23/00; H01L 23/31

(52) U.S. Cl. CPC H01L 23/49816; H01L 23/3171; H01L 23/3185; H01L 23/49838; H01L 24/13; H01L 24/16; H01L 24/17; H01L 24/20; H01L 24/24; H01L 24/73; H01L 23/49833; H01L 2224/13111; H01L 2224/13139; H01L 2224/13147; H01L 2224/13155; H01L 2224/16014; H01L 2224/16227; H01L 2224/17132; H01L 2224/17133; H01L 2224/17177; H01L 2224/215; H01L 2224/2401; H01L 2224/2405; H01L 2224/24226; H01L 2224/244; H01L 2224/73209; H01L 2924/15311; H01L 2924/182

(57) ABSTRACT

In examples, a semiconductor package comprises a semiconductor die having a device side comprising circuitry formed therein; a passivation layer abutting the device side; first and second horizontal metal members coupled to the device side by way of vias extending through the passivation layer, the first and second horizontal metal members having thicknesses ranging from 4 microns to 25 microns; first and second metal posts coupled to and vertically aligned with the first and second metal members, respectively, the first and second metal posts having vertical thicknesses ranging from 10 microns to 80 microns; first and second solder bumps coupled to the first and second metal posts, respectively; and a ball grid array (BGA) substrate coupled to the first and second solder bumps. The BGA substrate comprises a substrate member; first and second horizontal top metal members abutting the substrate and coupled to the first and second solder bumps, respectively; first and second vias coupled to the first and second horizontal top metal members and extending through the substrate member; and first and second horizontal bottom metal members abutting the substrate and coupled to the first and second vias, respectively. The first horizontal top metal member, the first via, and the first horizontal bottom metal member are electrically coupled to a signal terminal of the semiconductor die and are configured to provide signal currents. The second horizontal top metal member, the second via, and the second horizontal bottom metal member are electrically coupled to a power terminal of the semiconductor die and are configured to provide power currents.

### BACKGROUND

During manufacture, semiconductor chips (also commonly referred to as “dies”) are typically mounted on die pads of lead frames and are wire-bonded, clipped, or otherwise coupled to leads of the lead frame. Other devices may similarly be mounted on a lead frame pad. The assembly is later covered in a mold compound, such as epoxy, to protect the assembly from potentially damaging heat, physical trauma, moisture, and other deleterious factors. The finished assembly is called a semiconductor package or, more simply, a package. The leads are exposed to surfaces of the package and are used to electrically couple the packaged chip to devices outside of the chip.

However, other types of packages, such as chip-scale packages, may be configured differently than described above. Chip-scale packages include a die, metallic bumps (e.g., solder bumps), and a redistribution layer (RDL) that interfaces between the die and the metallic bumps so that signals are routed appropriately between the bumps and the active circuitry formed on the die.

### SUMMARY

In examples, a semiconductor package comprises a semiconductor die having a device side comprising circuitry formed therein; a passivation layer abutting the device side; first and second horizontal metal members coupled to the device side by way of vias extending through the passivation layer, the first and second horizontal metal members having thicknesses ranging from 4 microns to 25 microns; first and second metal posts coupled to and vertically aligned with the first and second metal members, respectively, the first and second metal posts having vertical thicknesses ranging from 10 microns to 80 microns; first and second solder bumps coupled to the first and second metal posts, respectively; and a ball grid array (BGA) substrate coupled to the first and second solder bumps. The BGA substrate comprises a substrate member; first and second horizontal top metal members abutting the substrate and coupled to the first and second solder bumps, respectively; first and second vias coupled to the first and second horizontal top metal members and extending through the substrate member; and first and second horizontal bottom metal members abutting the substrate and coupled to the first and second vias, respectively. The first horizontal top metal member, the first via, and the first horizontal bottom metal member are electrically coupled to a signal terminal of the semiconductor die and are configured to provide signal currents. The second horizontal top metal member, the second via, and the second horizontal bottom metal member are electrically coupled to a power terminal of the semiconductor die and are configured to provide power currents.

### BRIEF DESCRIPTION OF THE DRAWINGS

FIG. 1A is a perspective view of a semiconductor package including a semiconductor die and a ball grid array (BGA) substrate having signal and power conductors, in accordance with various examples.

FIG. 1B is a top-down view of a semiconductor package including a semiconductor die and a BGA substrate having signal and power conductors, in accordance with various examples.

FIG. 1C is a bottom-up view of a semiconductor package including a semiconductor die and a BGA substrate having signal and power conductors, in accordance with various examples.

FIG. 1D is a side view of a semiconductor package including a semiconductor die and a BGA substrate having signal and power conductors, in accordance with various examples.

FIG. 2A is a cross-sectional view of a semiconductor package including a semiconductor die and a BGA substrate having signal and power conductors, in accordance with various examples.

FIG. 2B is a perspective view of a semiconductor package including a semiconductor die and a BGA substrate having signal and power conductors, in accordance with various examples.

FIG. 2C is a top-down view of a semiconductor package including a semiconductor die and a BGA substrate having signal and power conductors, in accordance with various examples.

FIG. 2D is a top-down, multi-layer view of a semiconductor package including a semiconductor die and a BGA substrate having signal and power conductors, in accordance with various examples.

FIG. 2E is a top-down, multi-layer view of a semiconductor package including a semiconductor die and a BGA substrate having signal and power conductors, in accordance with various examples.

FIG. 3A is a perspective view of a semiconductor package including a semiconductor die and a BGA substrate having signal and power conductors, in accordance with various examples.

FIG. 3B is a cross-sectional view of a semiconductor package including a semiconductor die and a BGA substrate having signal and power conductors, in accordance with various examples.

FIG. 4 is a graph depicting insertion losses associated with a semiconductor package including a semiconductor die and a BGA substrate having signal and power conductors, in accordance with various examples.

FIG. 5 is a graph depicting return losses associated with a semiconductor package including a semiconductor die and a BGA substrate having signal and power conductors, in accordance with various examples.

FIG. 6 is a block diagram of a semiconductor package including a semiconductor die and a BGA substrate having signal and power conductors, in accordance with various examples.

### DETAILED DESCRIPTION

As technology progresses toward miniaturization, increasingly smaller circuit and semiconductor die sizes continue to be favored. Although circuits continue to shrink in size, the semiconductor dies on which the circuits are formed do not experience commensurate size reductions. Instead, semiconductor die sizes continue to be controlled by other factors, such as the logistical problems that occur when coupling the semiconductor die (such as a chip scale package) to a printed circuit board (PCB). For example, a very small die size makes it difficult to mount an adequate number of conductive terminals (e.g., “pins” or solder balls) to the die. A small die size, in tandem with a reduced number of conductive terminals, increases power and current densities, causing higher temperatures and degradation due to electromigration.

This disclosure describes various examples of a semiconductor package having a semiconductor die and a ball grid array (BGA) substrate coupled to the semiconductor die. The semiconductor die and the BGA substrate are configured to provide both signal and power currents. In addition, the BGA substrate has a “fan-out configuration.” In a fan-out configuration, the BGA substrate has a larger conductive terminal footprint than the semiconductor die, meaning that the BGA substrate interfaces with the small footprint of the conductive terminals of the semiconductor die, includes metallization within the BGA substrate that extends laterally toward the edges of the BGA substrate, and includes conductive terminals that couple to the metallization in the BGA substrate and have a wider footprint than those of the semiconductor die. In this way, BGA substrate enables the provision of both signal and power currents while simultaneously enabling substantial reductions in semiconductor die size and mitigating the power and current density, temperature, and electromigration challenges described above.

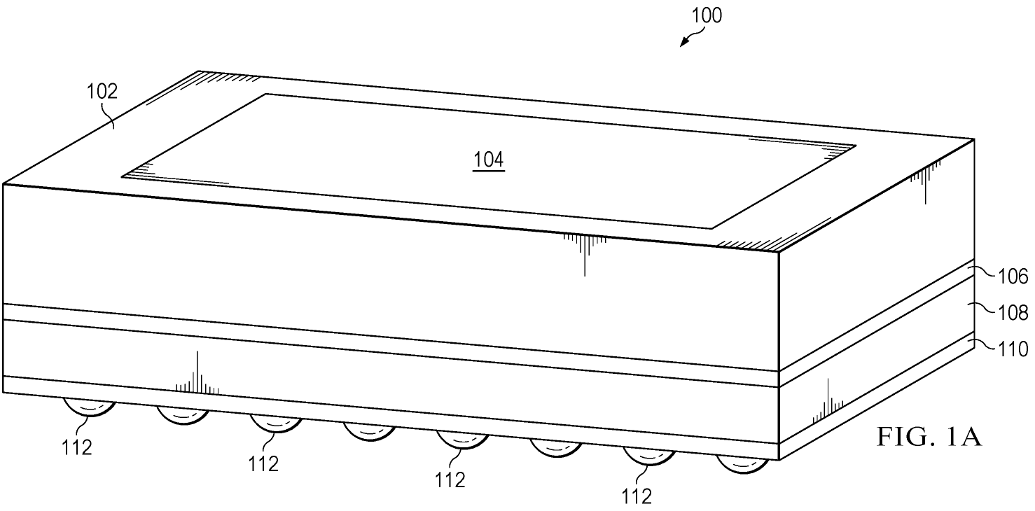

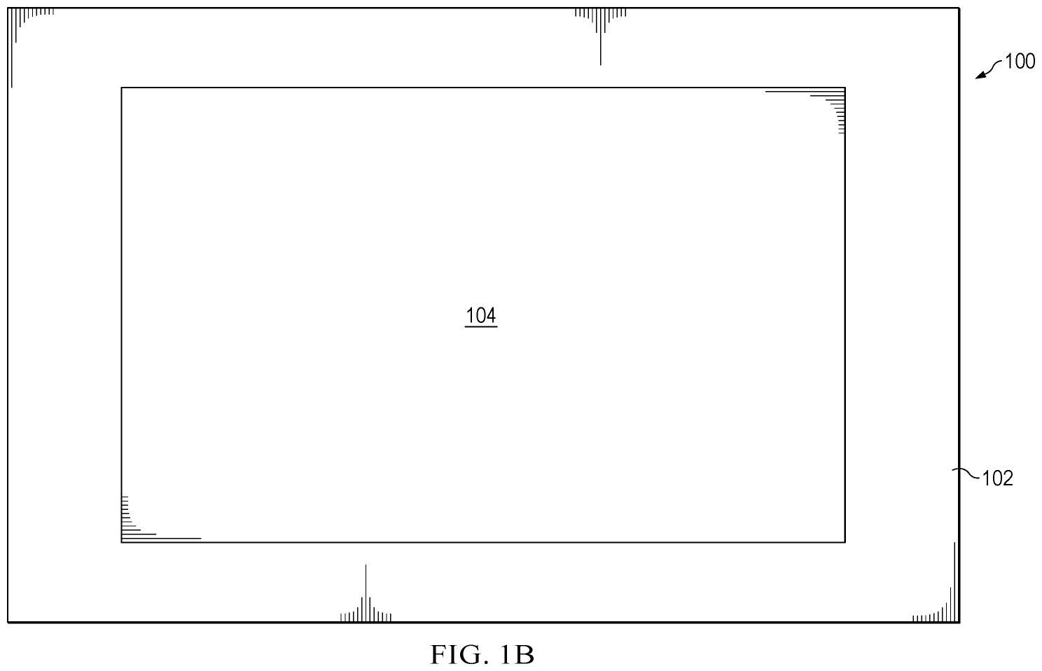

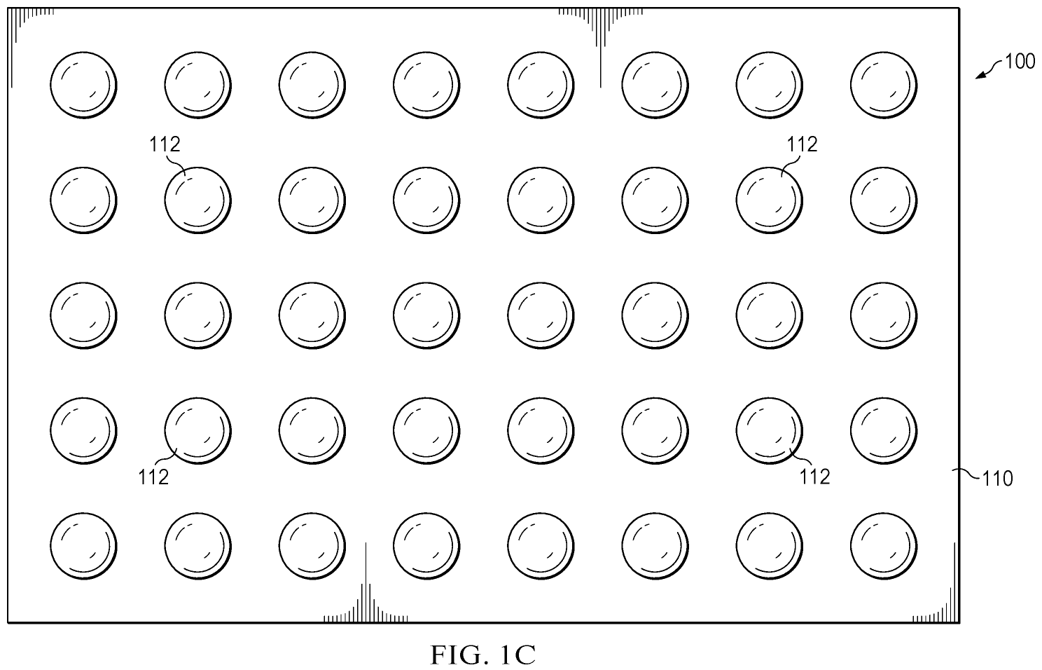

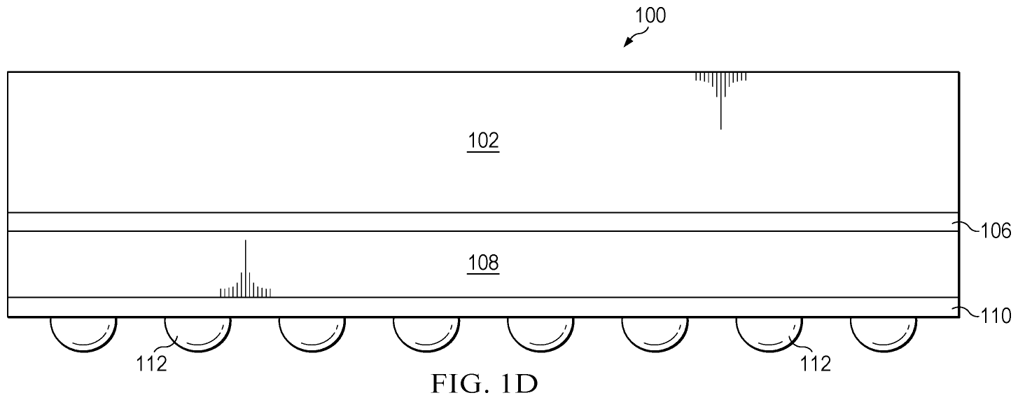

FIG. 1A is a perspective view of a semiconductor package 100 including a semiconductor die and a BGA substrate having signal and power conductors, in accordance with various examples. Signal currents are currents ranging from 1 nano ampere to 0.1 amperes, and power currents are currents ranging from 0.1 amperes to 100 amperes. The semiconductor package 100 includes a mold compound 102 and a semiconductor die 104. In examples, the mold compound 102 is opaque, and the view of FIG. 1A is not see-through, so only a top surface of the semiconductor die 104 is visible. In examples, the top surface of the semiconductor die 104 is flush with the top surface of the mold compound 102, as shown. In examples, the top surface of the semiconductor die 104 is within 200 microns, measured vertically, of the top surface of the mold compound 102. In examples, regardless of the leveling of the top surfaces of the semiconductor die 104 and the mold compound 102, the top surface of the semiconductor die 104 is exposed to an exterior of the semiconductor package 100, meaning that no mold compound covers the top surface of the semiconductor die 104. This configuration facilitates heat loss, keeping the semiconductor die 104 and other components within the semiconductor package 100 cool and operating properly. Portions of components within the semiconductor package 100 may be exposed to an exterior of the semiconductor package 100. For example, a solder mask 106 within the semiconductor package 100 may be exposed to an exterior of the semiconductor package 100, as shown. In examples, the exposed surfaces of the solder mask 106 are flush with outer surfaces of the semiconductor package 100, as shown. In examples, a BGA substrate 108 (e.g., polyimide, bismaleimide) may be exposed to an exterior of the semiconductor package 100, as shown. In examples, the exposed surfaces of the BGA substrate 108 are flush with outer surfaces of the semiconductor package 100, as shown. In examples, a solder mask 110 within the semiconductor package 100 may be exposed to an exterior of the semiconductor package 100, as shown. In examples, the exposed surfaces of the solder mask 110 are flush with outer surfaces of the semiconductor package 100, as shown. Solder balls 112 are coupled to a bottom surface of the semiconductor package 100. The solder balls 112 are coupled to signal and power conductors in the semiconductor package 100 and, when coupled to a printed circuit board (PCB), facilitate the exchange of signals and power between the semiconductor package 100 (and more specifically, the semiconductor die 104) and the PCB. As will be described below, the semiconductor die 104 has a smaller footprint (or perimeter) than the footprint (or perimeter) of the semiconductor package 100, because the semiconductor package 100 includes metal traces that “fan out” from a central area of the semiconductor package 100 (where the BGA substrate 108 couples to the semiconductor die 104) to a periphery of the semiconductor package, where these metal traces are coupled to solder balls 112.

FIG. 1B is a top-down view of the semiconductor package 100, in accordance with various examples. FIG. 1C is a bottom-up view of the semiconductor package 100, in accordance with various examples. FIG. 1D is a side view of the semiconductor package 100, in accordance with various examples.

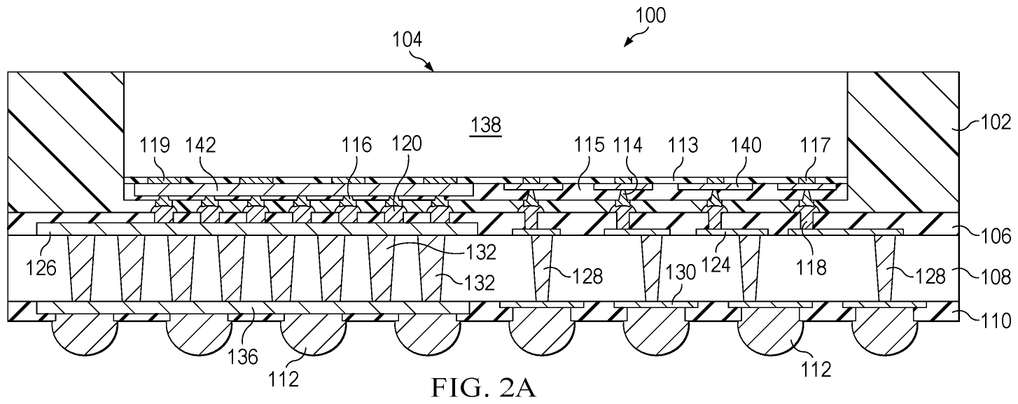

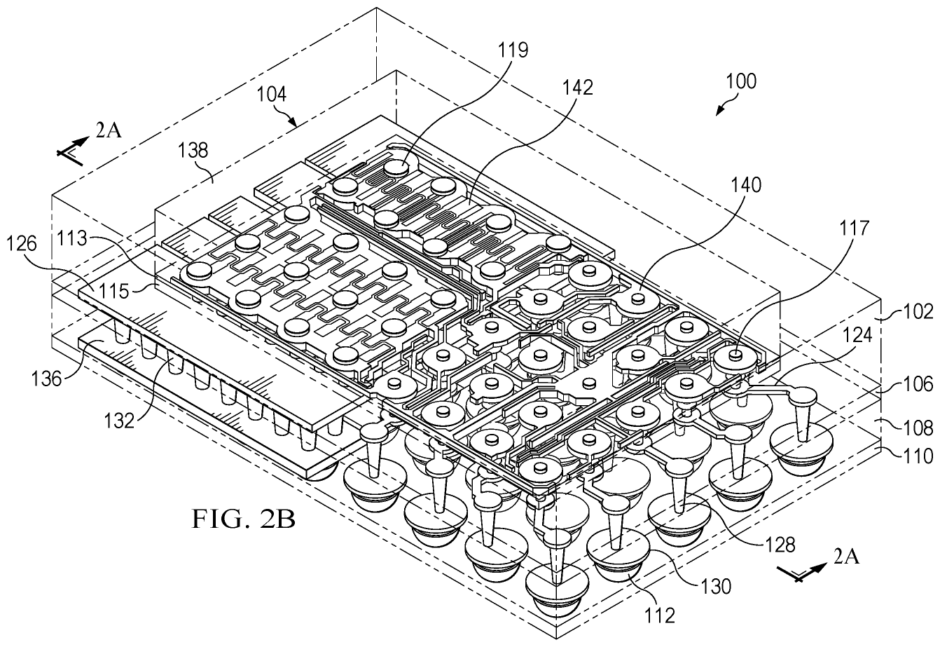

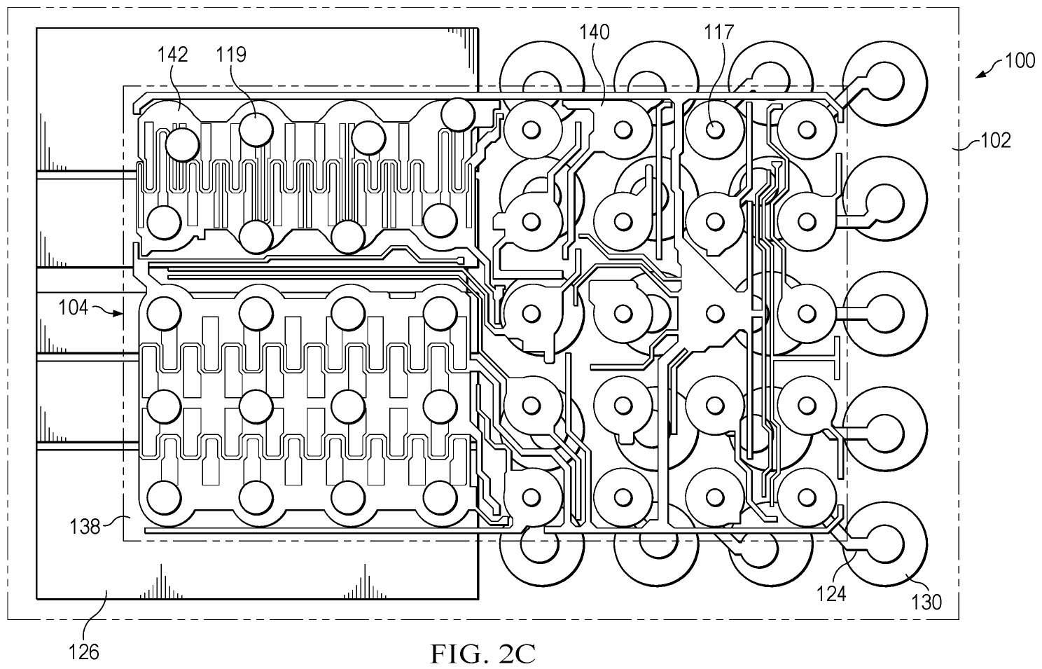

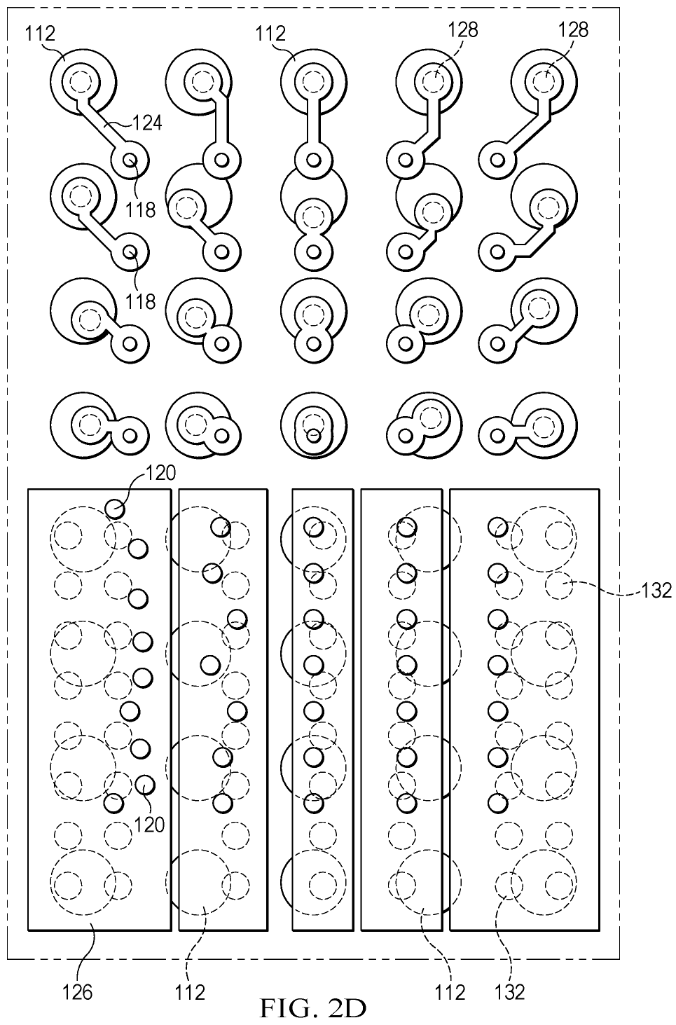

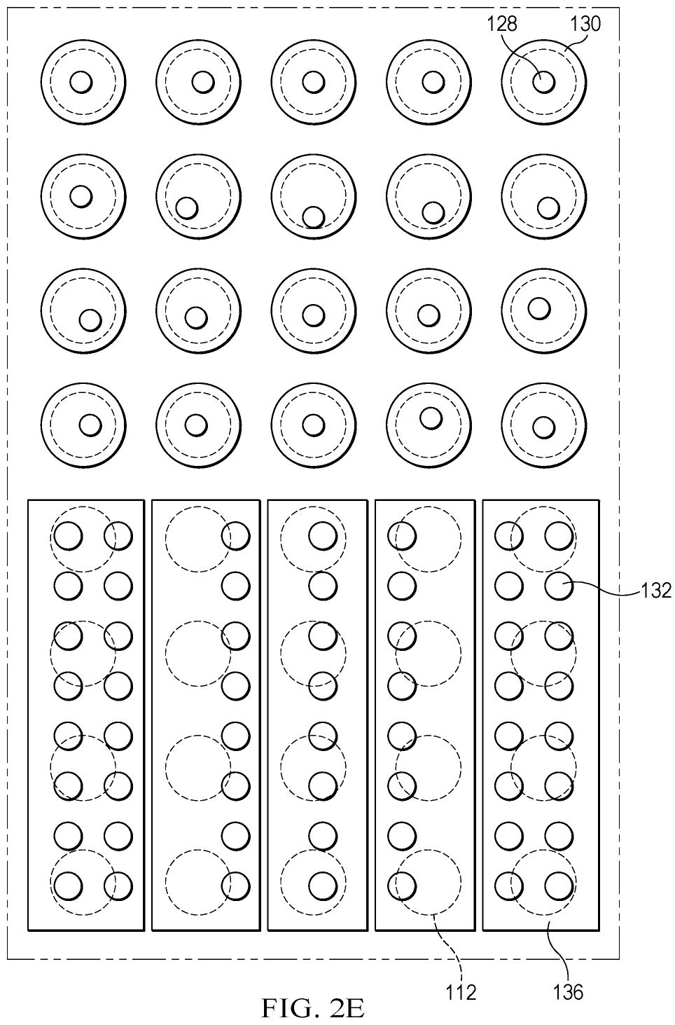

FIG. 2A is a cross-sectional view of the semiconductor package 100 including the semiconductor die 104 and the BGA substrate 108 having signal and power conductors, in accordance with various examples. More specifically, the semiconductor die 104 includes a semiconductor substrate 138 (e.g., silicon, gallium nitride); a device side on, in, and/or near which circuitry is formed; and a non-device side that includes a semiconductor substrate but does not include circuitry. The device side of the semiconductor die 104 faces downward, toward the bottom of the semiconductor package 100, and the non-device side of the semiconductor die 104 faces upward, toward the top of the semiconductor package 100. The device side of the semiconductor die 104 may include one or more metal layers (which are not expressly depicted in FIG. 2A) to facilitate the exchange of data signals and/or power. Collectively, these metal layers are referred to herein as “back end of line” (BEOL) metallization. The metal layers in the BEOL metallization may include aluminum or copper. The metal layers in the BEOL metallization have vertical thicknesses ranging from 0.2 microns to 3 microns, with a thickness below this range being disadvantageous because of unacceptably low current carrying ability, and with a thickness above this range being disadvantageous because of significantly diminished improvements in current carrying ability.

A planarized passivation layer 113 is on the device side of the semiconductor package 100. The passivation layer 113 protects circuitry in, on, and/or near the device side of the semiconductor package 100 from damage (e.g., oxidation). The semiconductor die 104 also includes a metal layer including metal members 140, 142 (e.g., copper). The metal members 140, 142 are oriented horizontally and thus may be referred to herein as horizontal metal members. Similarly, other metal members described herein that are oriented horizontally like the metal members 140, 142 may also be referred to herein as horizontal metal members. Non-metal members that are oriented horizontally may be referred to herein as horizontal members, horizontal components, etc. To be oriented horizontally, a structure must have its maximal dimension extending along the horizontal direction. As may be the case with any other components described herein (e.g., metal members 126, 136 described below), although only one metal member 142 is shown in the view of FIG. 2A, the scope of this disclosure is not limited to any particular number of metal members 142. Similarly, as may be the case with any other components described herein (e.g., metal members 124, 130 described below), although this description refers to metal member 140 in the singular sense for clarity of explanation, as FIG. 2A shows, multiple metal members 140 may be included. The metal member 140 may be configured to carry data signals and may be coupled to a data signal terminal, and the metal member 142 may be configured to carry power and may be coupled to a power terminal. The vertical thickness of the metal member 140 ranges from 4 microns to 25 microns, with a thickness below this range being disadvantageous because of unacceptably poor current carrying ability, and with a thickness above this range being disadvantageous because of significantly diminished improvements in current carrying ability. The metal member 142, which carries power, has a vertical thickness ranging from 10 microns to 25 microns, with a thickness below this range being disadvantageous because of unacceptably poor current carrying ability, and with a thickness above this range being disadvantageous because of significantly diminished improvements in current carrying ability.

The metal member 140 is coupled to the BEOL metallization (e.g., the BEOL metallization metal layer closest to the metal member 140) by way of vias 117 extending through the passivation layer 113. The metal member 142 is coupled to the BEOL metallization by way of vias 119 extending through the passivation layer 113. The vias 117 have a maximum cross-sectional diameter ranging from 1 micron to 10 microns, with a diameter below this range being disadvantageous because unacceptably high costs in patterning the via, and with a diameter above this range being disadvantageous because of unacceptably high inefficiencies in area usage. The metal member 142 is coupled to the BEOL metallization (e.g., the BEOL metallization metal layer closest to the metal member 142) by way of vias 119 extending through the passivation layer 113. The vias 119 have a maximum cross-sectional diameter ranging from 0.5 microns to 10 microns, with a diameter below this range being disadvantageous because of unacceptably high costs of patterning vias, and with a diameter above this range being disadvantageous because unacceptably high inefficiencies in area usage. The vias 117, 119 may comprise tungsten, copper, a suitable alloy, or any other suitable conductive material.

A polyimide layer 115 abuts the metal members 140, 142. The polyimide layer 115 has a vertical thickness ranging from 2 to 50 microns, with a thickness below this range being disadvantageous because of unacceptably reduced stress buffering ability, and with a thickness above this range being disadvantageous because of unacceptably increased costs. Another insulating and/or protective material may be useful in lieu of polyimide.

Metal posts 114, 116 are coupled to the metal members 140, 142, respectively. As FIG. 2A shows, the metal posts 114 are in vertical alignment with the metal members 140. As FIG. 2A also shows, the metal posts 116 are in vertical alignment with the metal member 142. To be in vertical alignment, a first structure must overlap with a second structure in the vertical direction. In examples, the metal posts 114, 116 comprise copper, although other metals and alloys may be suitable. The vertical thickness of the metal post 114, which is configured to carry data signals, ranges from 10 microns to 80 microns, with thicknesses below this range being disadvantageous because a standoff is necessary to apply underfill, and with thicknesses above this range being disadvantageous because of an unacceptable increase in form factor. The vertical thickness of the metal post 116, which is configured to carry power, ranges from 10 microns to 80 microns, with thicknesses below this range being disadvantageous because a standoff is necessary to apply underfill, and with thicknesses above this range being disadvantageous because of an unacceptable increase in form factor.

A solder bump 118 is coupled to the metal post 114, and a solder bump 120 is coupled to the metal post 116. The solder bumps 118, 120 comprise an alloy of tin (80-100%), silver (1-5%), copper (0-5%), and nickel (0-1%). The solder bump 118, which is configured to carry data signals, has a vertical thickness ranging from 10 microns to 80 microns, with a thickness less than this range being disadvantageous because a standoff is necessary to apply underfill, and with a thickness above this range being disadvantageous because of an unacceptable increase in form factor. The solder bump 120, which is configured to carry power, has a vertical thickness ranging from 10 microns to 80 microns, with a thickness less than this range being disadvantageous because a standoff is necessary to apply underfill, and with a thickness above this range being disadvantageous because of an unacceptable increase in form factor.

The BGA substrate 108 may be composed of any suitable material, such as FR-4, BT, polyimide, ABF, and epoxy. In some examples, the BGA substrate 108 includes a core, and in other examples, the BGA substrate 108 is coreless. The BGA substrate 108 has a vertical thickness ranging up to 500 microns, with a thickness above this range being disadvantageous because of an unacceptable increase in form factor. The solder mask 106 is on the BGA substrate 108. The solder mask 106 has a vertical thickness ranging from 5 to 30 microns, with a thickness below this range being disadvantageous because of a resulting lack of structural integrity, and with a thickness above this range being disadvantageous because of an unacceptable risk in form factor. The solder mask 106 is on metal members 124 and 126, which may be composed of any suitable metal or alloy, such as copper. The metal members 124 and 126 are also on the BGA substrate 108. The metal member 124 is configured to carry data signals, and the metal member 126 is configured to carry power. The metal member 124 has a vertical thickness ranging from 5 to 50 microns, with a thickness below this range being disadvantageous because of an unacceptably low level of current carrying capability and reliability, and with a thickness above this range being disadvantageous because of an unacceptable increase in form factor. The metal member 126 has a vertical thickness ranging from 5 to 50 microns, with a thickness below this range being disadvantageous because of an unacceptably low level of current carrying capability and reliability, and with a thickness above this range being disadvantageous because of an unacceptable increase in form factor.

Metal members 130 and 136 are on an opposite surface of the BGA substrate 108 from the surface of the BGA substrate 108 on which the metal members 124 and 126 are positioned. The metal member 130 is configured to carry data signals and has a vertical thickness ranging from 5 to 50 microns, with a thickness below this range being disadvantageous because of an unacceptably low level of current carrying ability and reliability, and with a thickness above this range being disadvantageous because of an unacceptable increase in form factor. The metal member 136 is configured to carry power and has a vertical thickness ranging from 5 to 50 microns, with a thickness below this range being disadvantageous because of reduced current carrying ability and reliability, and with a thickness above this range being disadvantageous because of an unacceptable increase in form factor.

One or more vias 128 couple the metal member 124 to the metal member 130 by extending through the BGA substrate 108. The one or more vias 128 are composed of any suitable metal or alloy, such as copper. Each of the one or more vias 128, which is configured to carry data signals, has a maximum cross-sectional diameter ranging from 20 to 120 microns, with a diameter below this range being disadvantageous because of an unacceptable increase in costs, and with a diameter above this range being disadvantageous because of an unacceptable increase in form factor.

One or more vias 132 couple the metal member 126 to the metal member 136 by extending through the BGA substrate 108. The one or more vias 132 are composed of any suitable metal or alloy, such as copper. Each of the one or more vias 132, which is configured to carry power, has a maximum cross-sectional diameter ranging from 20 to 120 microns, with a diameter below this range being disadvantageous because of an unacceptable increase in costs, and with a diameter above this range being disadvantageous because of an unacceptable increase in form factor.

The solder mask 110 abuts the metal members 130, 136 and the surface of the BGA substrate 108 on which the metal members 130, 136 are positioned. The solder mask 110 has a vertical thickness ranging from 5 to 30 microns, with a thickness below this range being disadvantageous because of an unacceptable increase in costs, and with a thickness above this range being disadvantageous because of an unacceptable increase in form factor.

Solder balls 112 are coupled to the metal members 130 and 136. The solder balls 112 comprise tin (60%-99.5%), silver (0.1%-5%), and copper (0.1%-3%), and thus may be referred to as SAC (“S” representing “Sn,” or tin; “A” representing “Ag,” or silver; and “C” representing “Cu,” or copper) solder balls. Such SAC solder balls 112 may mitigate voiding at the interface between solder and metal members 130, 136 caused by electromigration. The solder balls 112 have a maximum cross-sectional diameter ranging from 100 to 600 microns, with a diameter below this range being disadvantageous because of an unacceptable reduction in current carrying ability, and with a diameter above this range being disadvantageous because of an unacceptable increase in form factor. The solder balls 112 may couple to a PCB (not expressly shown in FIG. 2A).

In examples, the various structures of the semiconductor package 100 are covered by a mold compound 102, as shown. In some examples, the mold compound 102 is omitted.

FIG. 2B is a perspective view of the structure of FIG. 2A, in accordance with various examples. FIG. 2C is a top-down view of the structure of FIG. 2B, in accordance with various examples.

FIG. 2D is a top-down, multi-layer view of the semiconductor package 100, in accordance with various examples. FIG. 2E is a top-down, multi-layer view of the semiconductor package 100, in accordance with various examples. More particularly, FIGS. 2D and 2E show the BGA substrate 108 of FIGS. 2A-2C. To reduce complexity and manage space constraints, the semiconductor package 100 as shown in FIGS. 2D and 2E does not have the identical configuration of the semiconductor package 100 as shown in FIGS. 2A-2C, but the configurations are similar and exhibit the same novel features of FIGS. 2A-2C. FIG. 2D shows the solder bumps 118 configured to carry data signals and solder bumps 120 configured to carry power. The solder bumps 118 are coupled to metal members 124, which are configured to carry data signals, and the solder bumps 120 are coupled to metal members 126, which are configured to carry power. For example, the metal members 126 may be vertically thicker and horizontally larger (e.g., greater length and width) than the metal members 124. Vias 128, configured to carry data signals, extend downward toward the solder balls 112. Vias 132, configured to carry power, extend downward toward the solder balls 112. FIG. 2E shows the vias 128, configured to carry data signals, extending downward to couple to the metal members 130, which are configured to carry data signals, and which couple to solder balls 112. FIG. 2E also shows the vias 132, configured to carry power, extending downward to couple to the metal members 136, which are configured to carry power, and which couple to solder balls 112.

As FIGS. 2A-2D show, the top surface of the semiconductor die 104 may be exposed to an exterior of the mold compound 102. However, in some examples, the mold compound 102 may fully cover the semiconductor die 104, including the top surface of the semiconductor die 104. Exposing the top surface of the semiconductor die 104 achieves superior heat dissipation. In an experiment, a semiconductor die 104 exposed to an exterior of the semiconductor package 100 achieved a 2 degree Celsius reduction in maximum semiconductor die 104 temperature, a 3.5 degree Celsius per watt reduction in junction-to-ambient thermal resistance (theta-JA), and a 3 degree Celsius per watt reduction in junction-to-board thermal resistance (psi-JB), relative to a semiconductor package of the same structure but having a non-exposed top surface of the semiconductor die. Semiconductor packages 100 including metal layers having vertical thicknesses in the upper quartile of the thickness ranges provided above achieved a 0.6 degree Celsius reduction in maximum semiconductor die temperature, a 1 degree Celsius per watt reduction in theta-JA, and a 1.1 degree Celsius per watt reduction in psi-JB, relative to a semiconductor package of the same structure but having thinner metal layers. Semiconductor packages 100 including 2× or 3× the number of vias included in other semiconductor packages provided a 1 degree Celsius reduction in maximum semiconductor die temperature, a 0.9 degree Celsius per watt reduction in theta-JA, and a 1.5 degree Celsius per watt reduction in psi-JB. Semiconductor packages 100 including an exposed top surface of the semiconductor die 104, 2× to 3× the number of vias included in other semiconductor packages, and top-quartile metal member thicknesses as described above resulted in a 3.5 degree Celsius reduction in maximum semiconductor die temperature, a 6.3 degree Celsius per watt reduction in theta-JA, and a 5.6 degree Celsius per watt reduction in psi-JB, relative to semiconductor packages lacking these features.

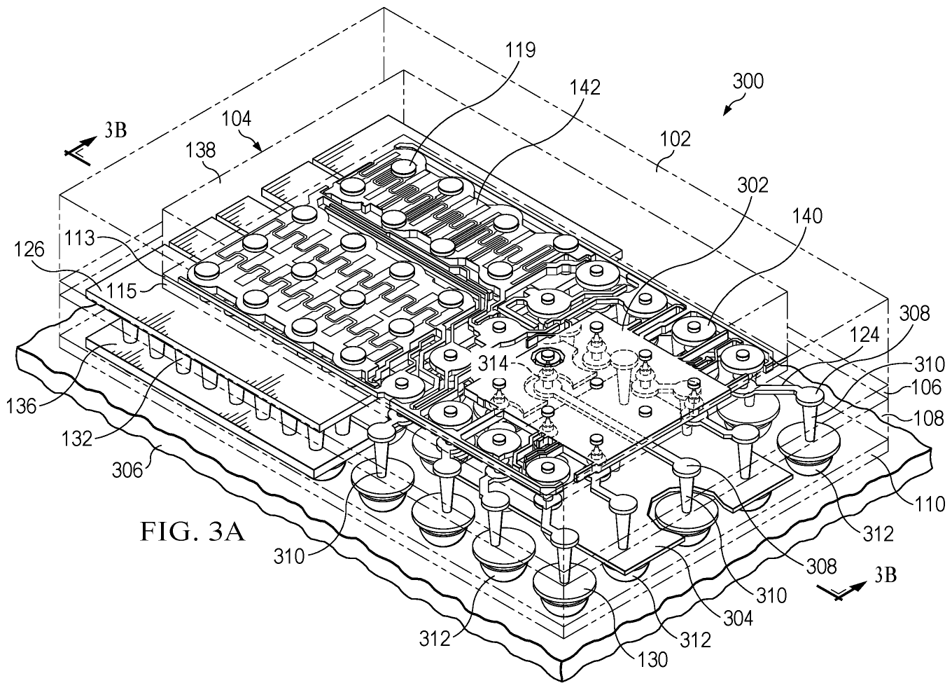

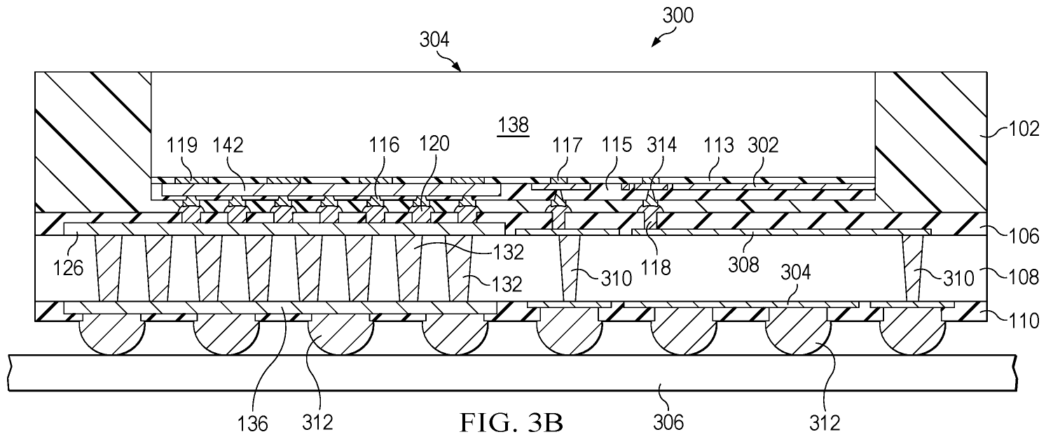

In some examples, the various metal members of the semiconductor package 100, such as the metal members 140, 142, 124, 126, 130, and 136 are coupled to and/or isolated from each other in such a manner that some of the metal members operate as ground planes and other metal members carry data signals or power. For instance, metal members carrying data signals and/or power may be positioned between a pair of ground planes. This configuration is useful to control impedance in the metal members carrying the data signals and/or power, and enables superior high-frequency performance. FIG. 3A is a perspective view of a semiconductor package 300, in accordance with various examples. The semiconductor package 300 includes metal members forming a ground plane 302, metal members forming a ground plane 304, and metal members 308 configured to carry data signals and/or power. A vertical plane extends through the ground plane 302, ground plane 304, and metal members 308, meaning these three components are in vertical alignment. Vias 314 couple the metal members 308 to circuitry on a semiconductor die (not expressly shown in FIG. 3A), and vias 310 couple the metal members 308 to solder balls 312. The vias 314 and 310 may extend through orifices in the ground planes 302 and 304 so as to avoid contact with the ground planes 302 and 304. The solder balls 312 may couple to a PCB 306. FIG. 3B is a cross-sectional view of the structure of FIG. 3A, in accordance with various examples.

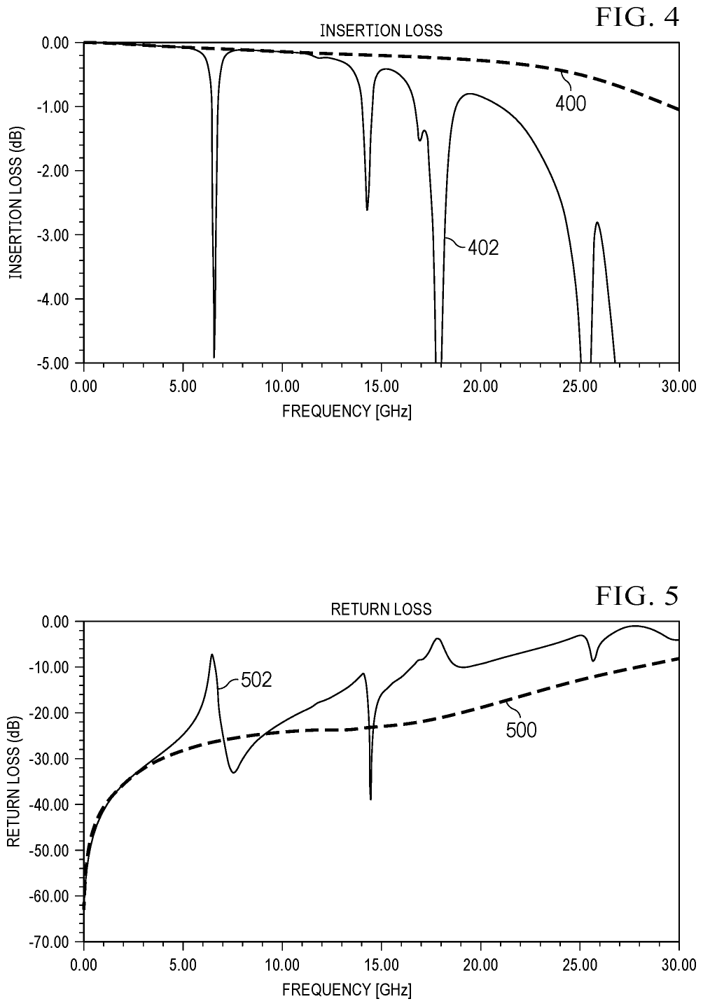

The semiconductor package 300 provides superior insertion and return losses relative to other types of semiconductor packages. The semiconductor package 300 provides no resonance in a wide frequency range from 0 GHz to 30 GHz because of controlled impedance in the metal members configured to carry data signals and/or power, as described above. The ground plane 304 between the metal members 308 and the PCB 306 shields the metal members 308 from negative effects of the PCB 306. FIG. 4 is a graph depicting superior insertion losses associated with the semiconductor package 300, in accordance with various examples. A curve 400 shows superior insertion losses relative to other packages, the insertion losses of which are represented by curve 402. FIG. 5 is a graph depicting return losses associated with the semiconductor package 300, in accordance with various examples. A curve 500 shows superior return losses relative to other packages, the return losses of which are represented by curve 502.

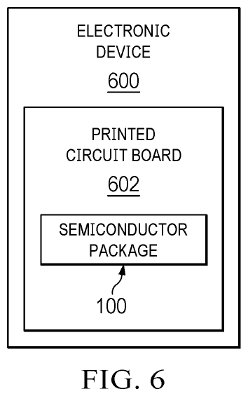

FIG. 6 is a block diagram of an electronic device comprising the semiconductor package described herein, in accordance with various examples. Specifically, an electronic device 600 includes a PCB 602, and the semiconductor package 100 is coupled to the PCB 602. Examples of the electronic device 600 include smartphones, laptop computers, desktop computers, tablets, notebooks, consumer electronics, appliances, vehicles (including electric vehicles), aircraft, and spacecraft.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die having a device side comprising circuitry formed therein;
a passivation layer abutting the device side;
first and second horizontal metal members coupled to the device side by way of vias extending through the passivation layer, the first and second horizontal metal members having thicknesses ranging from 4 microns to 25 microns;
first and second metal posts coupled to and vertically aligned with the first and second metal members, respectively, the first and second metal posts having vertical thicknesses ranging from 10 microns to 80 microns;
first and second solder bumps coupled to the first and second metal posts, respectively; and
a ball grid array (BGA) substrate coupled to the first and second solder bumps, the BGA substrate comprising:
a substrate member;
first and second horizontal top metal members abutting the substrate and coupled to the first and second solder bumps, respectively;
first and second vias coupled to the first and second horizontal top metal members and extending through the substrate member; and
first and second horizontal bottom metal members abutting the substrate and coupled to the first and second vias, respectively,
wherein the first horizontal top metal member, the first via, and the first horizontal bottom metal member are electrically coupled to a signal terminal of the semiconductor die and are configured to provide signal currents,
wherein the second horizontal top metal member, the second via, and the second horizontal bottom metal member are electrically coupled to a power terminal of the semiconductor die and are configured to provide power currents.

2. The package of claim 1, wherein the signal currents range from 1 nano ampere to 0.1 amperes, and wherein the power currents range from 0.1 amperes to 100 amperes.

3. The package of claim 1, further comprising a polyimide layer abutting the passivation layer and the first and second metal members.

4. The package of claim 1, wherein the first and second solder bumps have vertical thicknesses ranging from 10 microns to 80 microns.

5. The package of claim 1, wherein the second via has a horizontal cross-sectional diameter ranging from 20 microns to 120 microns.

6. The package of claim 1, further comprising a tin-silver-copper (SAC) solder ball coupled to the second horizontal bottom metal member.

7. The package of claim 1, wherein the device side of the semiconductor die faces toward the BGA substrate.

8. The package of claim 1, further comprising multiple vias extending through the substrate and coupling the second horizontal top and bottom metal members to each other, the second via included among the multiple vias.

9. The package of claim 1, further comprising a solder mask abutting the second horizontal bottom metal member and a bottom surface of the substrate member, wherein the solder mask includes gaps where the solder mask does not abut the second horizontal bottom metal member.

10. The package of claim 9, wherein the package includes a fan-out configuration such that a perimeter of the BGA substrate is larger than a perimeter of the semiconductor die.

11. The package of claim 1, further comprising a mold compound covering at least part of the semiconductor die.

12. The package of claim 11, wherein a top surface of the semiconductor die is exposed to an exterior of the mold compound.

13. The package of claim 1, wherein a vertical plane coincides with the first horizontal top metal member, a first horizontal ground metal member coupled to the device side of the semiconductor die, and a second horizontal ground metal member abutting a bottom surface of the substrate, the first horizontal top metal member positioned between the first and second horizontal ground metal members.

14. A semiconductor package, comprising:
a semiconductor die having a device side including circuitry formed therein;
a passivation layer abutting the device side, the passivation layer having metal vias formed therein;
first and second horizontal metal members coupled to the metal vias and electrically coupled to a power terminal of the semiconductor die, the second horizontal metal member configured to carry power current;
first and second metal posts in vertical alignment with the first and second horizontal metal members, respectively;
first and second solder bumps coupled to the first and second metal posts, respectively; and
a ball grid array (BGA) substrate coupled to the first and second solder bumps, the BGA substrate having metallization electrically coupled to a signal terminal of the semiconductor die and to the power terminal of the semiconductor die and configured to carry signal currents and power currents,
wherein the package has a fan-out configuration such that a perimeter of the BGA substrate is larger than a perimeter of the semiconductor die.

15. The semiconductor package of claim 14, further comprising a polyimide layer abutting the first and second horizontal metal members.

16. The semiconductor package of claim 14, wherein the first and second horizontal metal members have vertical thicknesses ranging from 4 microns to 25 microns, the first and second metal posts have vertical thicknesses ranging from 10 microns to 80 microns, and the first and second solder bumps have vertical thicknesses ranging from 10 microns to 80 microns.

17. The semiconductor package of claim 14, wherein the first and second solder bumps include tin in a range of 80% to 100%, silver in a range of 1% to 5%, copper in a range of 0% to 5%, and nickel in a range of 0% to 1%.

18. A semiconductor package, comprising:
a semiconductor die having a device side including circuitry formed therein;
a passivation layer abutting the device side, the passivation layer having metal vias formed therein;
first and second horizontal metal members coupled to the metal vias, the second horizontal metal member coupled to a power terminal of the semiconductor die and configured to carry power current;
first and second metal posts in vertical alignment with the first and second horizontal metal members, respectively;
first and second solder bumps coupled to the first and second metal posts, respectively;
a ball grid array (BGA) substrate coupled to the first and second solder bumps, the BGA substrate having a first metallization coupled to a signal terminal of the semiconductor die and configured to carry signal currents, and a second metallization coupled to the power terminal of the semiconductor die and configured to carry power currents, the second metallization comprising a third horizontal metal member having a vertical thickness ranging from 5 microns to 50 microns and a via having a horizontal cross-sectional diameter ranging from 20 microns to 120 microns; and
a mold compound covering at least part of the semiconductor die, wherein a top surface of the semiconductor die is exposed to an exterior of the mold compound.

19. The semiconductor package of claim 18, wherein the first and second horizontal metal members have vertical thicknesses ranging from 4 microns to 25 microns, the first and second metal posts have vertical thicknesses ranging from 10 microns to 80 microns, and the first and second solder bumps have diameters ranging from 10 microns to 80 microns.

20. The semiconductor package of claim 18, wherein the metal vias have cross-sectional diameters ranging from 0.5 microns to 10 microns and include at least one of tungsten and copper.
